(19) United States
(12) Patent Application Publication
(10) Pub. No.: US 2012/0094418 A1
(43) Pub. Date: Apr. 19, 2012

(54) Wafer Level Package and Manufacturing Method Using Photodefinable Polymer for Enclosing Acoustic Devices

(75) Inventors: George Grama, Sanford, FL (US); Christophe Zinck, Orlando, FL (US); Charles Carpenter, Orlando, FL (US)

(73) Assignee: TRIQUINT SEMICONDUCTOR, INC.

(21) Appl. No.: 12/906,689

(22) Filed: Oct. 18, 2010

(51) Int. Cl. H01L 21/50

(52) U.S. Cl. 438/51; 438/118; 257/E21.499

(57) ABSTRACT

A wafer level package is produced by forming a photo definable polymer into a frame structure around a device located on a device wafer while maintaining the polymer in a partially cured state. Additional polymer material is used form a cap structure on a carrier wafer. The cap structure is attached to the frame structure so as to place the device within a cavity, wherein sufficient pressure is applied to the cap structure to hold the frame structure via a bonding of the partially cured photo definable polymers. The bonding is characterized by adhesion strength greater than the adhesion strength securing the cap structure to the carrier wafer. The carrier wafer is separated from the device wafer with a force sufficient for separating the carrier wafer from the cap structure while the cap structure remains attached to the frame structure.

### FIELD OF THE INVENTION

The present invention relates to packaged electrical devices and in particular to wafer level packaged acoustic wave devices.

### BACKGROUND OF THE INVENTION

Typically, a wafer level package device includes a device wafer, comprising a Si, GaAs, LiTaO3, LiNbO3, or glass material, and the like, with an active area on a surface of the material that needs to be protected. To realize a clear cavity on an active area, a common technique is to use a sacrificial layer on carrier wafer that will support the pattern to transfer. The carrier wafer is the bonded to the device wafer and released either by etching, thermal decomposition or viscosity change of the sacrificial material.

By way of example and as described in U.S. Pat. No. 7,288,435 to Aigner et al., one method for producing a cover for a region of a substrate includes first producing a frame structure in a defined region of the substrate, and then attaching a cap structure to the frame structure so that the region under the cap structure is covered. As a result, sensitive devices may be protected from external influences and particularly from a casting material for casting the entire packaged device, which typically results when a diced chip is cast. One method described for producing such covers for a plurality of regions on a system wafer, each region having a device, wherein contact pads for the devices are provided outside each region, comprises producing a frame structure for each region of the system wafer. The step of producing the frame structure includes spinning a photostructurable epoxy resin material onto the system wafer, exposing the photostructurable epoxy resin material, developing the photostructurable epoxy resin material, and removing the epoxy resin material defined by the exposure to obtain the frame structure for each region of the system wafer. A support wafer having a sacrificial layer is provided for attaching a cap structure for attaching the cap structure to the frame structure so that the region between the cap structure and the system wafer is covered. The cap producing step includes spinning a photostructurable epoxy resin material onto the sacrificial layer on the support wafer and structuring the photostructurable epoxy resin material to produce a cap structure. The method further includes connecting the cap structure with the frame structure and removing the sacrificial layer from the support wafer to separate the cap structure from the support wafer, wherein the structuring occurs when producing the cap structure prior to removing the sacrificial layer or after the step of removing the sacrificial layer.

Typically, the cavity created by the frame and cap structures need to be cleared of any residue coming from the sacrificial layer. Further, the carrier wafer is typically recycled for it is not left in a reusable condition. It is desirable to be able to manufacture the above described cover for the devices without the need for a sacrificial layer and the costly steps associated with its use.

### SUMMARY OF THE INVENTION

In view of the foregoing background, one embodiment of the invention is directed to a method based on creating a clear cavity over an active area by using a carrier wafer holding either a cap pattern or the cavity itself that will be bonded and then transferred (debonding) on the device wafer without using any sacrificial material or temporary material. The invention teaches a technique using a poor interface adhesion between the carrier wafer and the negative photo sensitive epoxy.

One embodiment of the invention is realized in a method for producing a wafer level package. The method may comprise positioning a plurality of devices on a surface of a device wafer and forming an electrically non-conducting frame structure on the device wafer around each of the plurality of devices. A surface of a carrier wafer is coated with an adhesive material having low surface adhesion strength and a cap structure is placed onto the coated surface of the carrier wafer for temporarily attaching the cap structure to the carrier wafer. A bonding material is placed on the frame structure or the cap structure, with the bonding material being such that it has greater adhesion strength than the adhesive material. The cap structure is attached to the frame structure via the bonding material. The carrier wafer may then be separated from the cap structure and thus the device wafer with a force sufficient for separating the carrier wafer from the cap structure while maintaining the cap structure attachment to the frame structure. The carrier wafer may be reused after cleaning as desired.

The method may further include the step of coating a surface of the carrier wafer with an adhesive material comprising the step coating the surface of the carrier wafer with a photosensitive polymer. Yet further, the step of coating the surface of the carrier wafer with a photosensitive polymer may comprise coating the surface with an SUB epoxy. As desired, the carrier wafer separating step may comprise applying heat.

The method may further comprise a metallization layer on the surface of the carrier wafer, wherein the adhesive material is coated onto the metallization layer. The metallization layer may be applied by sputtering or evaporating a metallic material onto the surface of the carrier wafer. Yet further, the metallization layer may result from coating the carrier wafer with Ti/Ni, Ti/Au, or Ti/AICu (99/1).

### BRIEF DESCRIPTION OF THE DRAWINGS

For a fuller understanding of the invention, reference is made to the following detailed description, taken in connection with the accompanying drawings illustrating various embodiments of the present invention, in which:

FIG. 1 is a diagrammatical cross sectional view illustrating wafer level packaging according to the teachings of the present invention;

FIG. 1A is a diagrammatical top view of a wafer illustrating cut lines for separating the wafer into discrete packages;

FIG. 2 is a diagrammatical cross sectional view illustrating a device and frame structure on a device wafer;

FIG. 3 is a diagrammatical cross sectional view illustrating a cap structure temporarily attached to a carrier wafer;

FIG. 4 is a diagrammatical cross sectional view illustrating the cap structure and carrier wafer of FIG. 3 manipulated to attach the cap structure onto the frame structure carried by device wafer of FIG. 2;

FIG. 5 is a diagrammatical cross sectional view illustrating the carrier wafer being separated from the cap structure.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

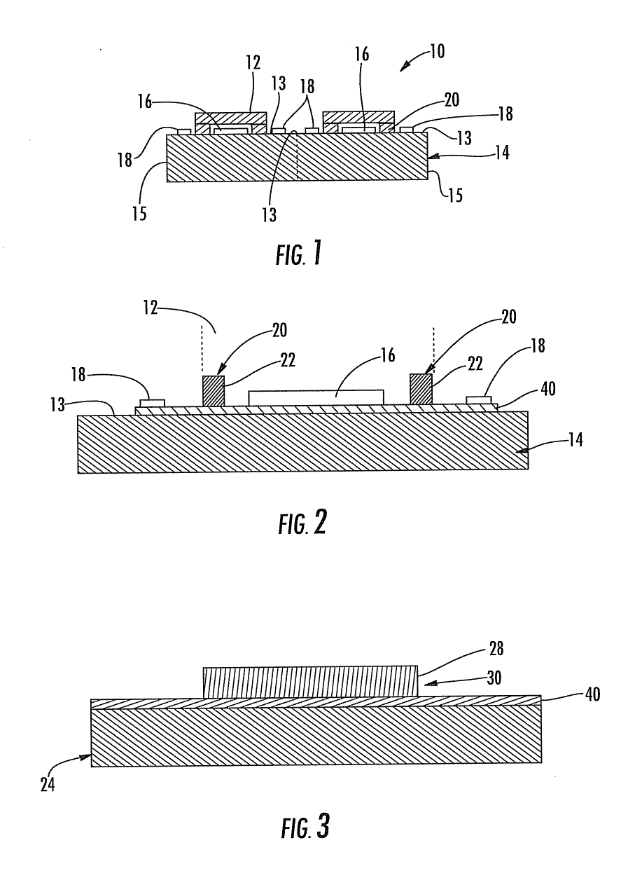

With reference initially to FIG. 1, one method according to the teachings of the present invention produces a wafer level package 10 for a plurality of regions 12 on a surface 13 of the device wafer 14. For the embodiment herein described by way of example, each region 12 comprises a device 16, wherein contact pads 18 for each device are provided outside each region, but within streets or cuts 15 as further illustrated with reference to FIG. 1A.

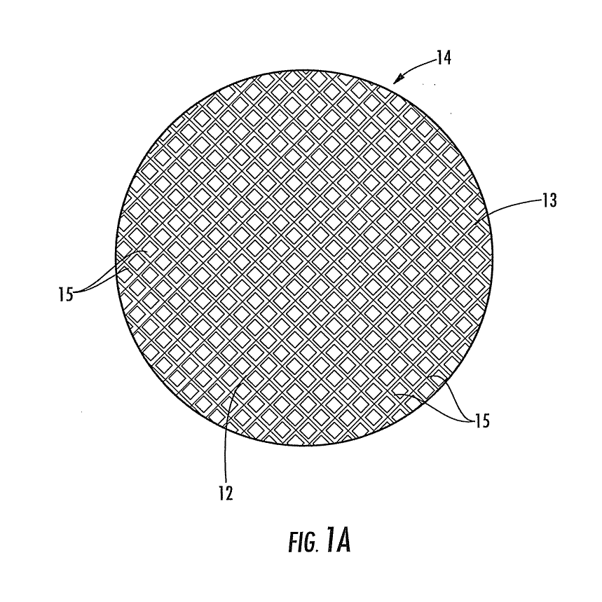

With continued reference to FIG. 1 and now to FIG. 2, one method for producing the wafer level package 10 comprises positioning a plurality of the devices 16 on a surface 13 of the device wafer 14. A frame structure 20 is formed around each device 16 using a first photo definable polymer 22. The first photo definable polymer 22 in maintained at partially cured state.

As illustrated with reference to FIG. 3, a carrier wafer 24 includes a surface 26 characterized by a first adhesion strength. The surface 26 is coated with a second photo definable polymer 28 so as to form a cap structure 30 for each of the plurality of devices 16. The second photo definable polymer 28 is preferably maintained at a partially cured state. Yet further, the polymers are preferable an electrically non-conducting material for the examples herein described.

By way of example, epoxy resins used as photo definable polymers are well known to be classified in three stages, A, B and C. It is also generally well known that the A-Stage for an epoxy resin refers to an early stage in a reaction of certain thermosetting resins in which the material is fusible and still soluble in certain liquids. The B-Stage refers to an intermediate stage in which the material generally softens when heated and swells when in contact with certain liquids, but may not entirely fuse or dissolve. Uncured resins are usually in this B-Stage. The C-Stage is a final stage in the reaction in which the material is relatively insoluble and infusible. Certain thermosetting resins in a fully cured state are in this C-Stage.

While the polymers 22, 28 are in the partially cured state (state A or B, by way of example), the cap structure 30 is attached to the frame structure 20 so as to place the devices 16 within a cavity 32, wherein sufficient pressure, force, or heat 34 is applied to the cap structure, frame structure, or both to bond the frame structure to the cap structure via a bonding of the partially cured photo definable polymers 22, 28. The bonding is characterized by second adhesion strength greater than the first adhesion strength securing the cap structure 30 to the carrier wafer 24.

As illustrated with reference to FIG. 5, the carrier wafer 24 is separated from the device wafer 14 with a force 36 sufficient for separating the carrier wafer from the cap structure while the cap structure remains attached to the frame structure 20. The polymers are cured to form the finished structure enclosing the device.

For multiple device structures as earlier described with reference to FIG. 1, individual wafer packages 10 may then be formed through typical dicing or cutting methods. Such a process may be used for manufacturing MEMS, SAW, BAW, and microfluidic devices, by way of example. The method may include applying heat 38 during the carrier wafer separating step.

One embodiment of the invention makes use of a relatively poor adhesion interface between an SU8 photo sensitive epoxy used for both the first and second polymers 22, 28, where the SU8 photo sensitive epoxy is used to from the frame and cap structures 20, 30.

By way of further example, and with reference again to FIG. 1, the embodiment is herein described for manufacturing a SAW/duplexer/BAW comprising the device substrate 14 formed from LiTaO3, LiNbO3, or Si. As illustrated with reference again to FIG. 2, the carrier wafer 24 may be the same material type of substrate used for the device wafer 14.

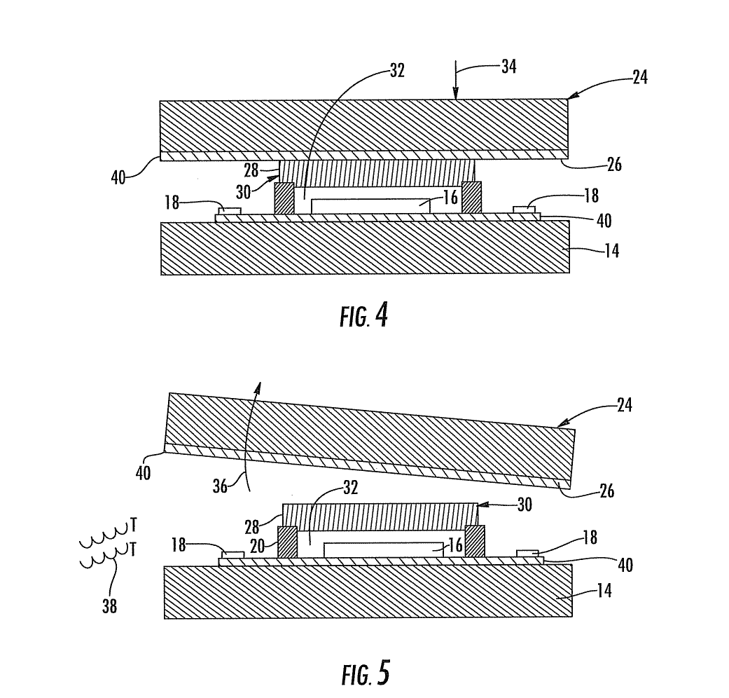

Using an SU8 photo sensitive epoxy for the polymers 22, 28, the polymers may be coated directly onto the surface 26 of the carrier wafer 24 if the carrier wafer is made of LiNbO3. Alternatively, the SU8 photo sensitive epoxy may be coated onto a metallization layer 40 that has been sputtered or evaporated onto the surface 24 of the carrier wafer 22. If used, the metallization layer 40 illustrated with reference to FIGS. 2-5 may comprise Ti/Ni; Ti/Au; or Ti/AICu (99/1), by way of example, or may only be the SU8. As a result, temporary patterns may be realized on the carrier wafer 24. Applying a surface coating may include applying a fluorocarbon based material, a glass material or gold. Alternatively, the surface may receive a plasma treatment sufficient for affecting its adhesion strength.

Using the SU8 polymer, permanent structures, such as the cap 30 and the frame 20, can be applied on the carrier wafer 24 and the device wafer 14, respectively, by various techniques such as spin coating, lamination for dry films, or spray coating. By way of example, the first polymer may be formed into the frame structure around each of the plurality of devices by spinning an epoxy resin material onto the device wafer, exposing the epoxy resin material, developing the epoxy resin material, and removing the epoxy resin material defined by the exposure to obtain the frame structure. Forming the second polymer into a cap structure may likewise include spinning an epoxy resin material onto the carrier wafer and structuring the epoxy resin material to produce the cap structure.

As above provided and with reference to FIG. 5, the permanent material of the cap and frame structures, in a desired pattern is transferred to the device wafer by using a polymer to polymer bonding applied to a surface or opposing surfaces of the cap structure and the frame structure, by way of example. For the example herein described by way of example, a polymer frame structure is made of the same polymer material and formed on the device substrate as the polymer cap structure formed on the carrier substrate using photolithography techniques. Again the material can be spin coated, spray coated or laminated. As illustrated with reference to FIG. 5, the cap structure, or any patterns developed are able to be transferred without undesirable residues coming from the carrier wafer. The carrier substrate may then be re-used after cleaning.

In an alternate embodiment, and as illustrated with reference again to FIG. 3, the cap structure 30 may be placed onto the surface 26 of the carrier wafer 24 for temporarily attaching the cap structure to the carrier wafer via one adhesive material selected for its low surface adhesion strength. A bonding material may then be placed on the frame structure 20 or the cap structure 30, wherein the bonding material is selected such that it has greater adhesion strength than the adhesive material.

The process of the present invention above described desirably avoids using a sacrificial layer to transfer patterns from the carrier to the device wafer. When using a sacrificial layer in the transfer steps, cavity pattern or structure then needs to be cleaned of any residues coming from the sacrificial layer used and the carrier wafer if recycled. Therefore, one clear benefit desirable by those skilled in the art includes no need for a sacrificial material and no need for cleaning the transferred structure.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A method for producing a wafer level package, the method comprising:
providing a device wafer;
positioning a plurality of devices on a surface of the device wafer;
coating the surface of the device wafer with a first photo definable polymer;
forming the first photo definable polymer into a frame structure around each of the plurality of devices;
maintaining the first photo definable polymer in a partially cured state;
providing a carrier wafer having a surface thereon characterized by a first adhesion strength;
coating the surface of the carrier wafer with a second photo definable polymer, the second definable polymer adhered to the carrier wafer with the first adhesion strength;
forming the second photo definable polymer into a cap structure for each of the plurality of devices;
maintaining the second photo definable polymer in a partially cured state;
attaching the cap structure to the frame structure so as to place the plurality of devices within a plurality of cavities formed thereby;
applying at least one of sufficient pressure and heat to at least one of the cap structure and the frame structure for bonding the cap structure to the frame structure via a bonding of the partially cured photo definable polymers, the bonding characterized by a second adhesion strength greater than the first adhesion strength securing the cap structure to the carrier wafer; and
separating the carrier wafer from the device wafer with a force sufficient for separating the carrier wafer from the cap structure while the cap structure remains attached to the frame structure while applying heat during the carrier wafer separating step.

2. The method according to claim 1, wherein providing a carrier wafer having a surface thereon characterized by the first adhesion strength comprises the step of treating the surface of the carrier wafer for affecting the adhesion strength.

3. The method according to claim 2, wherein the treating step comprises the step of applying a surface coating to the surface of the carrier wafer.

4. The method according to claim 3, wherein the surface coating applying step comprises applying at least one of applying a fluorocarbon based material, a glass material and gold.

5. The method according to claim 2, wherein the treating step comprises the step of a plasma treatment of the surface.

6. The method according to claim 1, wherein the steps of forming the first and second photo definable polymer comprise providing similar first and second photo definable polymers.

7. The method according to claim 6, wherein providing the first and second polymers comprise providing an SU8 epoxy resin.

8. (canceled)

9. The method according to claim 1, further comprising applying a bonding material on selected portions of at least one of the frame structure and the cap structure.

10. The method according to claim 1, wherein providing the device wafer comprises providing a substrate material of at least one of Lithium Tantalate (LiTaO3), Lithium Niobate (LiNbO3), and Silicon (Si).

11. The method according to claim 1 A method for producing a wafer level package, the method comprising:
providing a device wafer;
positioning a plurality of devices on a surface of the device wafer;
coating the surface of the device wafer with a first photo definable polymer;
forming the first photo definable polymer into a frame structure around each of the plurality of devices;
maintaining the first photo definable polymer in a partially cured state;
providing a carrier wafer having a surface thereon characterized by a first adhesion strength;
applying a metallization layer on the surface of the carrier wafer;
coating the surface of the carrier wafer having the metalization layer thereon with a second photo definable polymer, the second definable polymer adhered to the carrier wafer with the first adhesion strength;
forming the second photo definable polymer into a cap structure for each of the plurality of devices, wherein the cap structure forming comprises forming the cap structure on the metalization layer;
maintaining the second photo definable polymer in a partially cured state;
attaching the cap structure to the frame structure so as to place the plurality of devices within a plurality of cavities formed thereby;
applying at least one of sufficient pressure and heat to at least one of the cap structure and the frame structure for bonding the cap structure to the frame structure via a bonding of the partially cured photo definable polymers, the bonding characterized by a second adhesion strength greater than the first adhesion strength securing the cap structure to the carrier wafer having the metalization layer thereon; and
separating the carrier wafer from the device wafer with a force sufficient for separating the carrier wafer from the cap structure while the cap structure remains attached to the frame structure.

12. The method according to claim 11, wherein the metallization layer applying step comprises at least one of sputtering and evaporating a metallic material onto the surface of the carrier wafer.

13. The method according to claim 11, wherein applying the metallization layer comprises coating the carrier wafer with at least of a Titanium Nickel alloy (Ti/Ni), Titanium Gold alloy (Ti/Au), and a Titanium, Aluminum and Copper stack having 99 to 1 weight percent of Aluminum to Copper (Ti/AlCu (99/1)).

14. The method according to claim 11, wherein providing the device wafer comprises providing a substrate material of at least one of Lithium Tantalate (LiTaO3), Lithium Niobate (LiNbO3), and Silicon (Si).

15. The method according to claim 1, wherein forming the first photo definable polymer into a frame structure around each of the plurality of devices comprises:
spinning an epoxy resin material onto the device wafer;
exposing the epoxy resin material;
developing the epoxy resin material; and
removing the epoxy resin material defined by the exposure to obtain the frame structure.

16. The method according to claim 1, wherein forming the second photo definable polymer into a cap structure comprises:
spinning an epoxy resin material onto the carrier wafer; and
structuring the epoxy resin material to produce the cap structure.

17. The method according to claim 1, wherein the device comprises at least one of a microelectromechanical system (MEMS), surface acoustic wave (SAW), bulk acoustic wave (BAW), and microfluidic device.

18. The method according to claim 1, wherein coating the surface of the device wafer with a first photo definable polymer for forming the frame structure comprises coating an electrically non-conducting epoxy on the device wafer around each of the plurality of devices.

19. The method according to claim 1, wherein forming the first and second photo definable polymers comprises at least one of spray coating the polymer and laminating the polymer.

20. A method for producing a wafer level package for a plurality of regions on a device wafer, each region comprising a device, wherein contact pads for each device are provided outside each region, the method comprising:
forming a frame structure on the device wafer around each of the plurality of devices;
providing a carrier wafer;
coating a surface of the carrier wafer with an adhesive material;
placing a cap structure onto the coated surface of the carrier wafer for attaching the cap structure to the carrier wafer via the adhesive material;
placing a bonding material on at least one of the frame structure and the cap structure, the bonding material having a greater adhesion strength than the adhesive material;
attaching the cap structure to the frame structure, wherein the cap structure is held to the frame structure via the bonding material; and
applying a separating force to the carrier wafer for separating the carrier wafer from the cap structure while applying heat thereto, and while maintaining the cap structure attachment to the frame structure.

21. The method according to claim 20, wherein the step of coating a surface of the carrier wafer comprises coating the surface of the carrier wafer with a photosensitive polymer.
